(19) United States
(12) Patent Application Publication
(10) Pub. No.: US 2009/0167973 A1
(43) Pub. Date: Jul. 2, 2009

(54) THIN FILM TRANSISTOR ARRAY PANEL AND METHOD FOR MANUFACTURING THE SAME, AND LIQUID CRYSTAL DISPLAY

(76) Inventors: Sun-Young CHANG, Bucheon (KR); Byoung-Joo Kim, Anyang-si (KR); Sang-Hun Lee, Suwon-si (KR); Gwan-Soo Kim, Seoul (KR)

Correspondence Address: Haynes and Boone, LLP;IP Section, 2323 Victory Avenue, SUITE 700, Dallas, TX, 75219, US

(21) Appl. No.: 12/242,374

(22) Filed: Sep. 30, 2008

(30) Foreign Application Priority Data
Dec. 27, 2007 (KR) 10-2007-0138887

(51) Int. Cl. G02F 1/1335; G02F 1/133; H01L 27/02

(52) U.S. Cl. 349/43; 349/106; 438/30; 257/E27.009

(57) ABSTRACT

An embodiment of the present invention relates to a thin film transistor array panel, which includes a substrate, a plurality of first thin film transistors formed on the substrate, a plurality of pixel electrodes connected to the first thin film transistors, a plurality of color filters formed under or on the pixel electrodes and displaying various colors, and a plurality of protecting members formed on the first thin film transistors, wherein the protecting members have substantially the same color.

### CROSS-REFERENCE TO RELATED APPLICATION

This application claims priority to and the benefit of Korean Patent Application No. 10-2007-0138887 filed in the Korean Intellectual Property Office on Dec. 27, 2007, the entire contents of which are incorporated herein by reference.

### BACKGROUND

(a) Technical Field

One or more embodiments of the present invention generally relate to a thin film transistor array panel, a method for manufacturing the same, and a liquid crystal display.

(b) Description of the Related Art

A flat panel display is a display device having a thickness that is small compared with the size of the screen. Liquid crystal display (LCD), plasma display panel (PDP), and organic light emitting device (OLED) are examples of widely used flat panel displays.

The LCD is a display device that displays images by using the electro-optical characteristics of liquid crystals in which light transmission amounts are varied according to the intensity of an applied electric field. The PDP is a display device that displays images by using plasma generated by gas discharge. In the OLED, electrons and holes are injected into an organic illumination layer respectively from a cathode (the electron injection electrode) and an anode (the hole injection electrode). The injected electrons and holes are combined to generate excitons, which illuminate when they convert from an excited state to a ground state.

Among the flat panel displays, an active matrix type is generally used, with each pixel independently controlled by switching elements such as thin film transistors. The thin film transistor may be classified as a top gate type or a bottom gate type according to the position of a gate electrode. Amorphous silicon or polysilicon is generally used as the semiconductor material to form a channel of the thin film transistor, wherein the amorphous silicon is widely used in the bottom gate type and the polysilicon is widely used in the top gate type.

In the bottom gate type, a gate electrode is disposed under a semiconductor member, and a source electrode and a drain electrode contact opposite sides of the semiconductor member. The channel of the thin film transistor is formed in a portion that is disposed between the source electrode and the drain electrode in the semiconductor, and is covered by an insulating layer.

The above information disclosed in this Background section is only for enhancing the understanding of the background of the invention. Therefore it may contain information that does not form prior art that would be known in this country to a person of ordinary skill in the art.

### SUMMARY

In general, if a channel of a semiconductor member and a source electrode and a drain electrode are formed without an additional protecting layer, the electrical characteristics thereof may be deteriorated by moisture or impurities. One or more embodiments of the present invention generally provide a thin film transistor array panel, a manufacturing method thereof, and a liquid crystal display to improve productivity as well as to simplify the manufacturing process by protecting the channel of the semiconductor member, the source electrode, and the drain electrode.

A thin film transistor array panel according to an exemplary embodiment of the present invention includes a substrate, a plurality of first thin film transistors formed on the substrate, a plurality of pixel electrodes connected to the first thin film transistors, a plurality of color filters formed under or on the pixel electrodes and displaying various colors, and a plurality of protecting members formed on the first thin film transistors, wherein the protecting members have substantially the same color.

The color of the color filters may be a first color, a second color, and a third color, and the color filters of the first color, the second color, and the third color may be alternately arranged according to one direction.

The protecting member may contact the first thin film transistor. The protecting member may be the same layer as the color filter of the first color. One of the protecting members may be connected to the color filter of the first color. The surface of the protecting members may be lower than the surface of the color filters. Furthermore, the protecting member may be disposed under the edges of the color filter of the second color and the color filter of the third color.

The thin film transistor array panel may further include a light blocking member on the protecting member. The thin film transistor array panel may further include a capping layer on the color filter and the light blocking member. The thin film transistor array panel may further include a storage electrode line formed on the substrate.

The pixel electrodes may respectively include a first subpixel electrode connected to the first thin film transistor, and a second subpixel electrode separated from the first subpixel electrode. The thin film transistor array panel may further include a plurality of second thin film transistors connected to the second subpixel electrodes. The area of the first subpixel electrode may be smaller than the area of the second subpixel electrode.

A liquid crystal display according to an exemplary embodiment of the present invention includes a plurality of thin film transistors, a plurality of pixel electrodes connected to the thin film transistors, a common electrode facing the pixel electrodes, a liquid crystal layer formed between the pixel electrodes and the common electrode, a plurality of color filters formed on or under the pixel electrode and displaying different colors, and a plurality of protecting members formed on the thin film transistors, wherein the protecting members have substantially the same color as the color filters.

A manufacturing method of a thin film transistor array panel according to an exemplary embodiment of the present invention includes forming a plurality of thin film transistors on a substrate, forming first color filters in first pixels in each group of first to third pixels, forming protecting members having the same color as the first color filters on the thin film transistors disposed on the first to third pixels of the groups, forming second color filters in the second pixels of the groups, forming third color filters in the third pixels of the groups, and forming a plurality of pixel electrodes on the first to third color filters.

The first, second, and third color filters may have different colors. The first color filter and the protecting member may be substantially simultaneously formed. The forming of the first color filter and the forming of the protecting member may include coating an organic material having one of blue, green, and red colors in the first to third pixels, respectively, of the groups, exposing the organic material by using a slit mask, and developing the exposed organic material.

The manufacturing method of the thin film transistor array panel may further include forming a light blocking member on the protecting member. The manufacturing method of the thin film transistor array panel may further include forming a capping layer on the first to third color filters and the light blocking members.

### BRIEF DESCRIPTION OF THE DRAWINGS

FIG. 1 is a cross-sectional view of a display device including a thin film transistor array panel according to one or more exemplary embodiments of the present invention,

FIG. 2 is a layout view of a liquid crystal display including a thin film transistor array panel and a common electrode panel according to one or more exemplary embodiments of the present invention,

FIG. 3 is a layout view of the thin film transistor array panel shown in FIG. 2,

FIG. 4 is a layout view of the common electrode panel shown in FIG. 2,

FIG. 5 is a cross-sectional view of the liquid crystal display shown in FIG. 2 taken along the line V-V,

FIG. 6 to FIG. 15 are cross-sectional views of a thin film transistor array panel showing intermediate processes of manufacturing the thin film transistor array panel according to one or more exemplary embodiments of the present invention,

FIG. 16 is a table showing the difference of the electrical capacity depending on whether the protecting member shown in FIG. 1 exists or not.

### DETAILED DESCRIPTION OF THE EMBODIMENTS

Embodiments of the present invention will be described more fully hereinafter with reference to the accompanying drawings, in which one or more exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

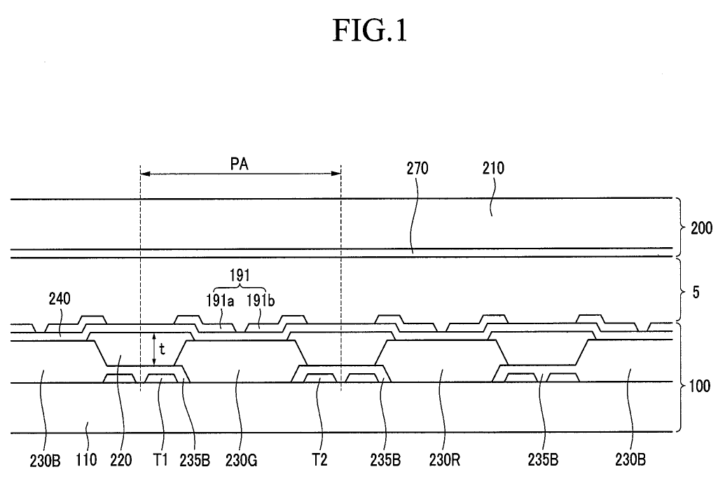

Now, a thin film transistor array panel according to an exemplary embodiment of the present invention will be described in detail with reference to FIG. 1.

FIG. 1 is a cross-sectional view of a display device including a thin film transistor array panel according to one or more exemplary embodiments of the present invention. Referring to FIG. 1, a display device includes a thin film transistor array panel 100, a common electrode panel 200, and an electric-optical active layer 5 formed between the two display panels 100 and 200.

Firstly, the thin film transistor array panel 100 will be described.

A plurality of thin film transistors T1 and T2 may be formed on a substrate 110 preferably made of an insulating material such as glass or plastic, and the first and second thin film transistors T1 and T2 may be disposed in one pixel PA. Alternatively, only one thin film transistor may be disposed in each pixel PA.

A protecting member 235B of a blue color may contact all the thin film transistors T1 and T2 that are disposed in the plurality of pixels PA. The protecting member 235B may have a different color.

Color filters 230B, 230G, and 230R of blue, green, and red may be alternately arranged in the plurality of pixels PA. The color filter 230B of blue may be connected to the protecting member 235B, and edge portions of the green and red color filters 230G and 230R may overlap the protecting member 235B. The height of the protecting member 235B may be lower than the height of the surface of the color filters 230B, 230G, and 230R from the surface of the substrate 110.

The protecting member 235B may be formed when forming the blue color filter 230B, and the difference between the height of the protecting member 235B and that of the blue color filter 230B may be formed by using a slit mask. The protecting member may alternatively be formed when forming the green color filter 230G or the red color filter 230R and may have a green color or a red color.

The thin film transistors T1 and T2 may be protected by the protecting member 235B such that a separate passivation layer that is normally necessary to protect the thin film transistors T1 and T2 from a developing solvent is not needed.

A light blocking member 220 may be formed on the protecting member 235B. The light blocking member 220 is referred to as a black matrix, and it prevents light leakage. The thickness t of the light blocking member 220 may be in the range of 1.5 μm to 3 μm. If the thickness t of the light blocking member 220 is less than 1.5 μm, its ability to prevent light leakage is decreased, and if the thickness t of the light blocking member 220 is larger than 3 μm, the manufacturing process of the light blocking member 220 is complicated. The light blocking member 220 may be designed to have the appropriate thickness by controlling the height of the protecting member 235B.

A capping layer 240 may be formed on the color filters 230B, 230G, and 230R and the light blocking member 220. The capping layer 240 prevents the color filters 230B, 230G, and 230R from lifting. The capping layer 240 also suppresses contamination of the electric-optical active layer 5 by organic material such as a solvent used in the formation of the color filters 230B, 230G, and 230R so as to prevent or reduce problems such as an afterimage that may be generated under various driving mode conditions.

A plurality of pixel electrodes 191 made of a transparent conductor such as ITO and IZO may be formed on the capping layer 240. A pixel electrode 191 that is disposed in one pixel PA may include first and second subpixel electrodes 191a and 191b, where the first and second subpixel electrodes 191a and 191b may be separated from each other. The first subpixel electrode 191a may be connected to the first thin film transistor T1, and the second subpixel electrode 191b may be connected to the second thin film transistor T2. The first subpixel electrode 191a and the second subpixel electrode 191b may respectively receive different voltages from the first and second thin film transistors T1 and T2.

Next, the common electrode panel 200 facing the thin film transistor array panel 100 will be described.

A common electrode 270 may be formed on an insulating substrate 210 made of transparent glass or plastic. The common electrode 270 may be made of a transparent conductor such as ITO or IZO, and may receive a common voltage. The common electrode 270 may alternatively be formed on the thin film transistor array panel 100. Also, a light blocking member may be formed between the substrate 210 and the common electrode 270.

The electric-optical active layer 5 may be formed between the common electrode panel 200 and the thin film transistor array panel 100. The material of the electric-optical active layer 5 is dependant on the kind of the display device; for example, it may be a liquid crystal material in a liquid crystal display, or it may be an organic light emitting material in an organic light emitting device.

According to the present exemplary embodiment, the thin film transistors T1 and T2 are protected by the protecting member 235B from the developing solvent. Furthermore, the protecting member 235B is made of a different organic material from an inorganic insulator and is disposed on the thin film transistors T1 and T2 such that the distance between the thin film transistors T1 and T2 and the pixel electrode 191 is increased. Additionally, the dielectric constant is reduced compared with the case in which only the light blocking member 220 is disposed on the thin film transistors T1 and T2, thereby reducing the parasitic capacitance.

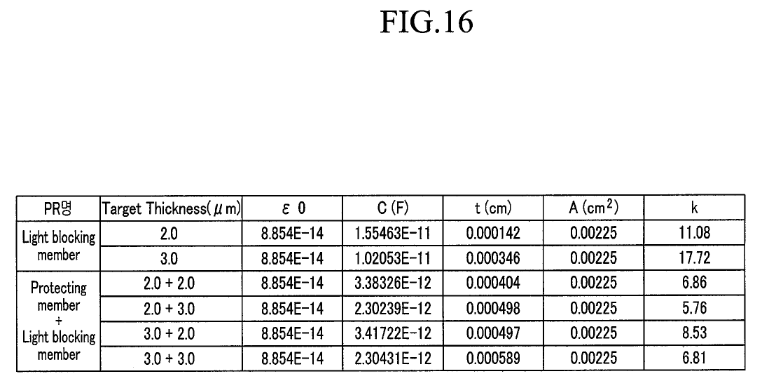

The effect of the reduction of the parasitic capacitance may be shown in FIG. 16. FIG. 16 is a table showing the difference of the electrical capacity depending on whether the protecting member shown in FIG. 1 exists or not. Referring to FIG. 16, ε₀ is the dielectric ratio of a vacuum, C is the electrical capacity, t is the thickness of the light blocking member 220 and the protecting member 235B if present, A is the area, and k is the dielectric constant. The dielectric constant k is a value found by dividing the dielectric ratio of the light blocking member and the protecting member if present by the dielectric ratio ε₀ of a vacuum. When only disposing the light blocking member, the dielectric constant is 11.08 or 17.72; however, when the light blocking member and the protecting member are disposed together, the dielectric constant is reduced to 6.86, 5.76, 8.53, or 6.81. According to the present exemplary embodiment, the light blocking member and the protecting member are formed together such that the electrical capacity, that is to say the parasitic capacitance, is reduced to 3.38326E-12, 2.30239E-12, 3.41722E-12, or 2.30431E-12.

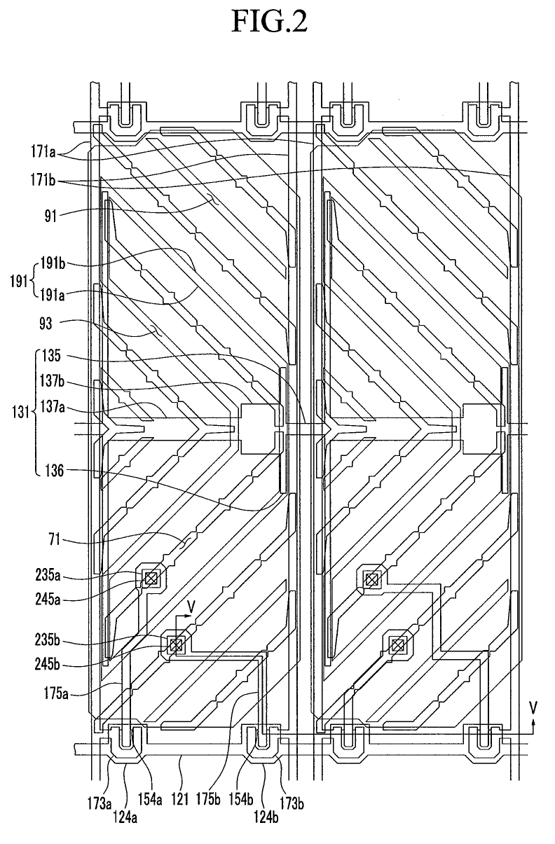

Next, a thin film transistor according to another exemplary embodiment of the present invention will be described with reference to FIG. 2 to FIG. 5.

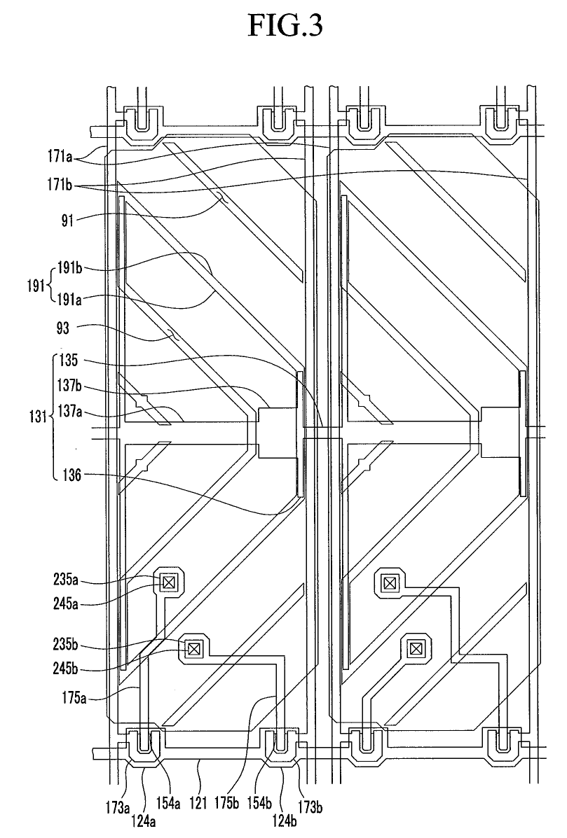

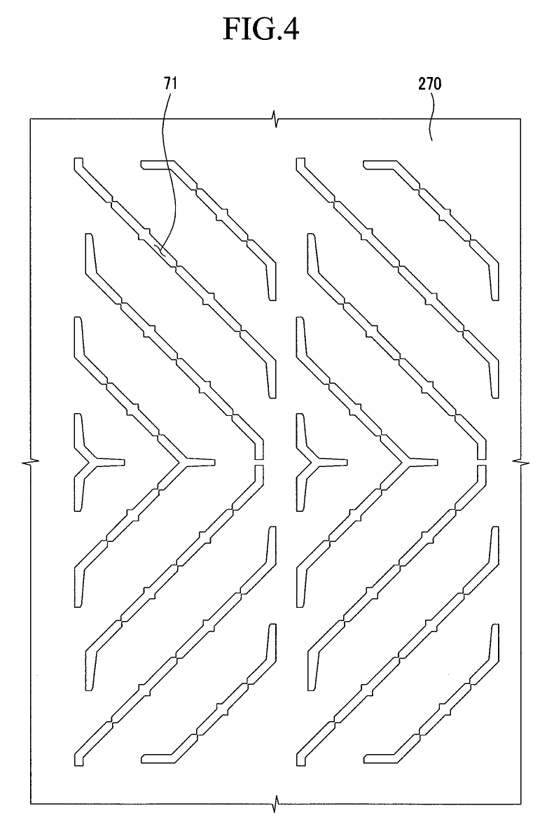

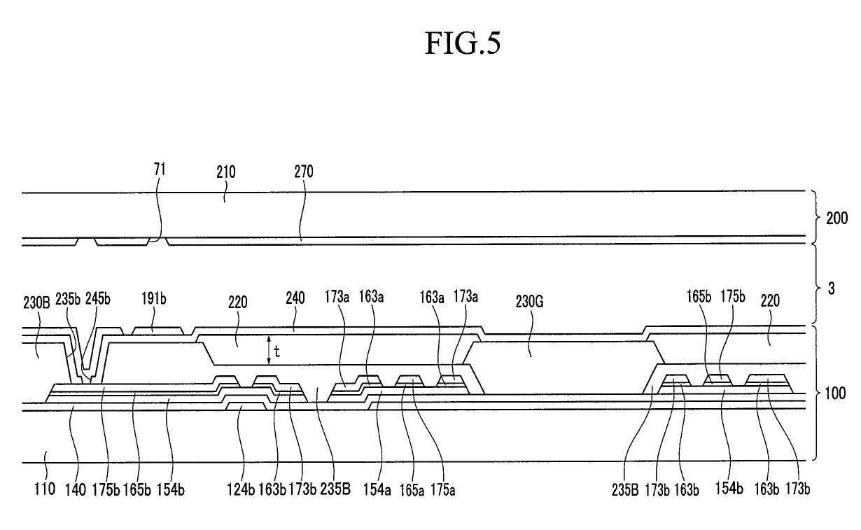

FIG. 2 is a layout view of a liquid crystal display including a thin film transistor array panel and a common electrode panel according to one or more exemplary embodiments of the present invention; FIG. 3 is a layout view of the thin film transistor array panel shown in FIG. 2; FIG. 4 is a layout view of the common electrode panel shown in FIG. 2, and FIG. 5 is a cross-sectional view of the liquid crystal display shown in FIG. 2 taken along the line V-V.

Referring to FIG. 2 to FIG. 5, a display device includes a thin film transistor array panel 100 and a common electrode panel 200 facing each other, and a liquid crystal layer 3 formed between the two display panels 100 and 200.

The liquid crystal layer 3 has negative dielectric anisotropy. The liquid crystal molecules of the liquid crystal layer 3 may be arranged such that a longitudinal axis of the liquid crystal molecules is perpendicular to the surfaces of the two panels when an electric field does not exist.

Alignment layers (not shown) may be applied on the inner surfaces of the display panels 100 and 200, and may be homeotropic alignment layers. At least one polarizer (not shown) may be attached on the outside surfaces of the display panels 100 and 200.

Firstly, the common electrode panel 200 will be described.

A common electrode 270 may be formed on an insulating substrate 210 made of transparent glass or plastic. The common electrode 270 may be made of a transparent conductor such as ITO or IZO, and may receive a common voltage. The common electrode 270 may include a plurality of cutouts 71. Each of the cutouts 71 may have at least one slanting portion substantially obliquely extended, and each slanting portion may have a plurality of notches that may be concave or convex.

Next, the thin film transistor array panel 100 will be described.

A plurality of gate lines 121 and a plurality of storage electrode lines 131 may be formed on an insulating substrate 110 that is preferably made of transparent glass or plastic.

The gate lines 121 may extend substantially in a transverse direction and transmit gate signals. Each gate line 121 may include a plurality of first and second gate electrodes 124a and 124b protruding upward and downward.

The storage electrode lines 131 may extend substantially in a transverse direction parallel to the gate lines, and are supplied with a predetermined voltage. Each storage electrode line 131 may be disposed between two neighboring gate lines 121 and may maintain the same interval from the two neighboring gate lines 121. The storage electrode lines 131 may include first and second storage electrodes 137a and 137b, a branch electrode 136, and a connection 135. The first and the second storage electrodes 137a and 137b may be approximately rectangular and connected to each other. The horizontal length of the first storage electrode 137a may be longer than that of the second storage electrode 137b, and the vertical length of the first storage electrode 137a may be shorter than that of the second storage electrode 137b. The branch electrode 136 may be connected to the end of the second storage electrode 137b, may extend in the vertical direction near the gate line 121, and the horizontal length thereof may be very short. The connection 135 may connect the branch electrode 136 to the neighboring first storage electrode 137a, and the vertical length thereof may be short compared with the first and second storage electrodes 137a and 137b. It is to be understood that the shapes and the arrangement of the storage electrode lines 131 may be modified in various ways without departing from the spirit or scope of the present invention.

A gate insulating layer 140 formed of silicon nitride (SiNx) or silicon oxide (SiOx) may be formed on the gate lines 121 and the storage electrode lines 131.

A plurality of first and second semiconductors 154a and 154b preferably formed of hydrogenated amorphous silicon (simply referred to as a-Si) or polysilicon may be formed on the gate insulating layer 140. The first semiconductors 154a may overlap the first gate electrodes 124a and the second semiconductors 154b may overlap the second gate electrodes 124b.

A pair of first ohmic contacts 163a and 165a may be formed on the first semiconductor 154a, and a pair of second ohmic contacts 163b and 165b may be formed on the second semiconductor 154b. The ohmic contacts 163a, 165a, 163b, and 165b may be formed of a material such as an n+ hydrogenated amorphous silicon doped with a high concentration of n-type impurity, or of silicide.

A plurality of first and second data lines 171a and 171b and a plurality of first and second drain electrodes 175a and 175b may be formed on the ohmic contacts 163a and 165a, and 163b and 165b, and on the gate insulating layer 140.

The first and the second data lines 171a and 171b transmit data signals, may extend substantially in the vertical direction, and may cross the gate lines 121 and the connection 135 of the storage electrode lines 131. The first data line 171a may include a first source electrode 173a that is extended toward the first gate electrode 124a and is curved with a “U” shape. Likewise, the second data line 171b may include a second source electrode 173b that is extended toward the second gate electrode 124b and is curved with a “U” shape.

The drain electrodes 175a and 175b are separated from the data lines 171a and 171b. Each drain electrode 175a and 175b may include one end enclosed by the source electrodes 173a and 173b and the other end having a wide area. The planer shape of the drain electrodes 175a and 175b may be variously changed. In FIG. 2, the wide portion of the first drain electrode 175a disposed in the left pixel is disposed closer to the storage electrode line 131 than the second drain electrode 175b, and the wide portion of the second drain electrode 175b disposed in the right pixel is disposed closer to the storage electrode line 131 than the first drain electrode 175a. However, the planer shape of the drain electrodes 175a and 175b may be the same in all pixels.

The first/second gate electrodes 124a/124b, the first/second source electrodes 173a/173b and the first/second drain electrodes 175a/175b form the first/second thin film transistors (TFT) along with the first/second semiconductors 154a/154b. The channels of the first/second thin film transistors are formed in the first/second semiconductors 154a/154b between the first/second source electrodes 173a/173b and the first/second drain electrodes 175a/175b.

The first TFT's ohmic contacts 163a and 165a, may only exist between the semiconductors 154a and the data lines 171a/source electrode 173a, and between the semiconductor 154a and the drain electrode 175a respectively, and reduce contact resistance between them. Likewise, the second TFT's ohmic contacts 163b and 165b, may only exist between the semiconductors 154b and the data lines 171b/source electrode 173b, and between the semiconductor 154b and the drain electrode 175b respectively, and reduce contact resistance between them. The semiconductors 154a and 154b may have portions that are exposed without being covered by the data lines 171a and 171b or by the drain electrodes 175a and 175b, including a region between the source electrodes 173a/173b and the drain electrodes 175a/175b.

Protecting members 235B of blue may be formed on the source electrodes 173a and 173b, the drain electrodes 175a and 175b, and the exposed semiconductors 154a and 154b disposed in the plurality of pixels PA. The protecting members 235B may have a different color, and they may overlap the data lines 171a and 171b and extend according thereto in the vertical direction.

Color filters 230B, 230G, and 230R of blue, green, and red may be alternately arranged between the first data line 171a and the second data line 171b of the plurality of pixels PA, and they may be elongated in a vertical direction along the data lines 171a and 171b to form a stripe. The color filters 230B, 230G, and 230R may be made of photosensitive organic materials including pigments, and may extend higher than the protecting members 235B. The blue color filter 230B may be connected to the protecting member 235B, and the boundaries of the green and red color filters 230G and 230R may overlap the protecting member 235B. The color filters 230B, 230G, and 230R may have a plurality of openings 235a and 235b.

The protecting member 235B may be formed when forming the blue color filter 230B, and may be formed to have a different height from the blue color filter 230B by using a slit mask. The protecting member may also be formed when forming the green color filters 230G or the red color filters 230R such that it may have a green or red color.

The data lines 171a and 171b, the drain electrodes 175a and 175b, and the exposed portions of the semiconductors 154a and 154b are protected from the developing solvent by the protecting member 235B.

A light blocking member 220 may be formed on the protecting member 235B. The thickness t of the light blocking member 220 may be in the range of about 1.5 μm to 3 μm. If the thickness t of the light blocking member 220 is less than 1.5 μm, its ability for light blockage is decreased, and if the thickness t is larger than 3 μm, the manufacturing process of the light blocking member 220 is complicated. The light blocking member 220 may be designed to have the appropriate thickness by controlling the height of the protecting member 235B.

A capping layer 240 may be formed on the color filters 230B, 230G, and 230R and the light blocking member 220. The capping layer 240 prevents the color filters 230B, 230G, and 230R from lifting. The capping layer 240 also suppresses contamination of the liquid crystal layer 3 by organic material such as a solvent used in the formation of the color filters 230B, 230G, and 230R so as to prevent or reduce problems such as an afterimage that may be generated under various driving mode conditions.

The capping layer 240 may be made of an inorganic insulator such as silicon nitride or silicon oxide. The capping layer 240 has a plurality of contact holes 245a and 245b exposing the wide end portion of the drain electrodes 175a and 175b, and the contact holes 245a and 245b may be positioned in the openings 235a and 235b.

A plurality of pixel electrodes 191 may be formed on the capping layer 240. The pixel electrodes 191 may be made of a transparent conductive material such as ITO or IZO, or a reflective metal such as aluminum, silver, chromium, or alloys thereof.

The pixel electrode 191 may include the first subpixel electrode 191a and the second subpixel electrode 191b, and the area of the first subpixel electrode 191a may be smaller than the area of the second subpixel electrode 191b.

The first subpixel electrode 191a may have a bent shape of an approximate unequal sign (<), and may be enclosed by the second subpixel electrode 191b via a gap 93 interposed therebetween. The second subpixel electrode 191b may include a plurality of cutouts 91 with a straight bent shape and may form an angle of about 45 degrees with respect to the gate lines 121 and the data lines 171a and 171b. The gap 93 may include a plurality of oblique portions parallel to the cutouts 91, and a plurality of vertical portions parallel to the data lines 171a and 171b. The cutouts 91 and the gaps 93 may be alternately arranged with the cutouts 71 of the common electrode 270.

The first/second subpixel electrodes 191a/191b may be connected to the first/second drain electrodes 175a/175b of the first/second thin film transistor through the contact holes 245a/245b. In FIG. 2, the first subpixel electrode 191a disposed in the left pixel may be connected to the first drain electrode 175a disposed in the left side, and the first subpixel electrode 191a disposed in the neighboring pixel on the right side may be connected to the second drain electrode 175b disposed in the right side.

The first/second subpixel electrodes 191a/191b may receive data voltages from the first/second drain electrodes 175a/175b. The first/second subpixel electrodes 191a/191b applied with the data voltages generate an electric field along with the common electrode 270 of the common electrode panel 200 such that the orientation of the liquid crystal molecules of the liquid crystal layer 3 between the two electrodes 191a/191b and 270 is determined. Accordingly, the luminance of the light transmitted through the liquid crystal layer 3 differs depending on the orientation of the liquid crystal molecules thus determined.

The first thin film transistor, the first subpixel electrode 191a, the liquid crystal layer 3, the common electrode 270, and the polarizer that are disposed on them, form a unit for displaying one luminance point that is referred to as the first subpixel hereafter. Also, the second thin film transistor, the second subpixel electrode 191b, the liquid crystal layer 3, the common electrode 270, and the polarizer that are disposed on them, form a unit for displaying one luminance point that is referred to as the second subpixel hereafter. The first subpixel and the second subpixel are combined to represent one effective luminance point, and they may be represented as one pixel for this reason.

The luminance presented by one pixel is determined by image information supplied from an external device (not shown), and the image information is processed in a controller (not shown) in the liquid crystal display and converted into voltages to apply to the first subpixel electrode and the second subpixel electrode. The voltages are determined so that the luminance average of the first subpixel and the second subpixel is the same as the luminance represented by the image information for the pixel.

Here, the luminance of the first subpixel is higher than the luminance of the second subpixel, and the voltage applied to the first subpixel electrode 191a is higher than the voltage applied to the second subpixel electrode 191b with reference to the common voltage in the case of a normally black mode.

The first/second subpixel electrodes 191a/191b and the common electrode 270 form first/second capacitors (called liquid crystal capacitors) to maintain the applied voltage even after the TFT is turned off. The first/second subpixel electrodes 191a/191b and the storage electrode line 131 also form a storage capacitor.

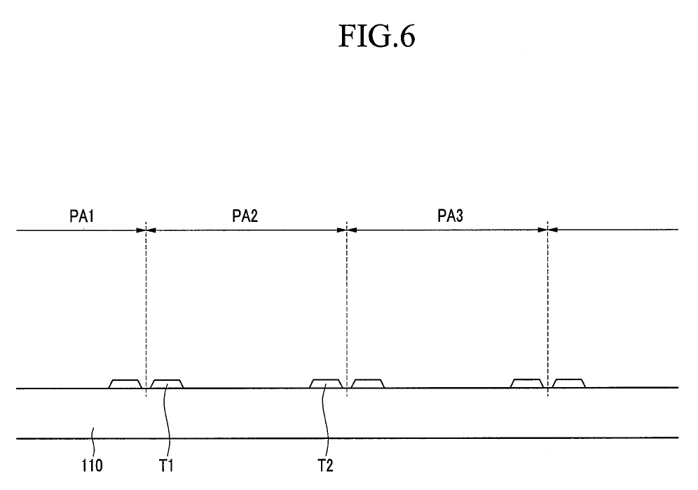

Next, a manufacturing method of the thin film transistor according to one or more exemplary embodiments of the present invention will be described with reference to FIG. 6 to FIG. 15.

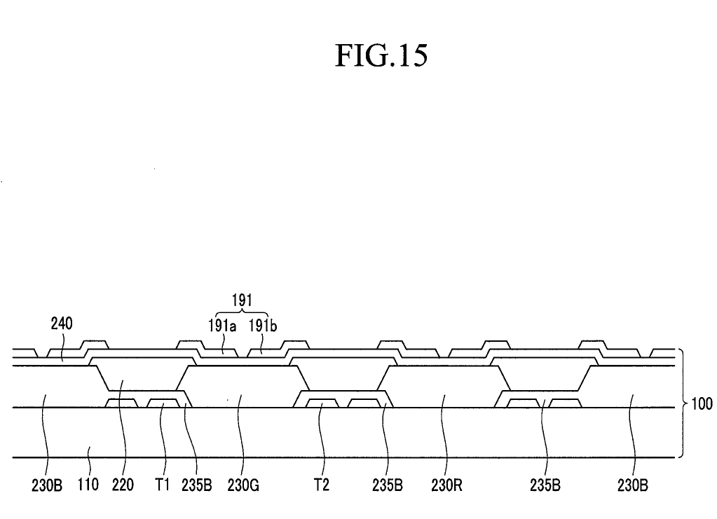

FIG. 15 is a cross-sectional view of the thin film transistor array panel shown in FIG. 1, and FIG. 6 to FIG. 14 are cross-sectional views of a thin film transistor array panel showing intermediate processes of manufacturing the thin film transistor array panel according to one or more exemplary embodiments of the present invention.

Firstly, as shown in FIG. 6, a plurality of thin film transistors T1 and T2 may be formed on a substrate 110. Two thin film transistors T1 and T2 may be disposed in each of the pixels PA1, PA2, and PA3.

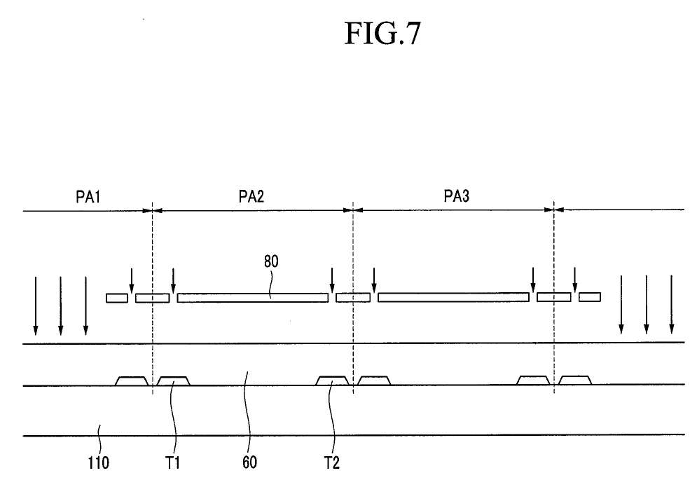

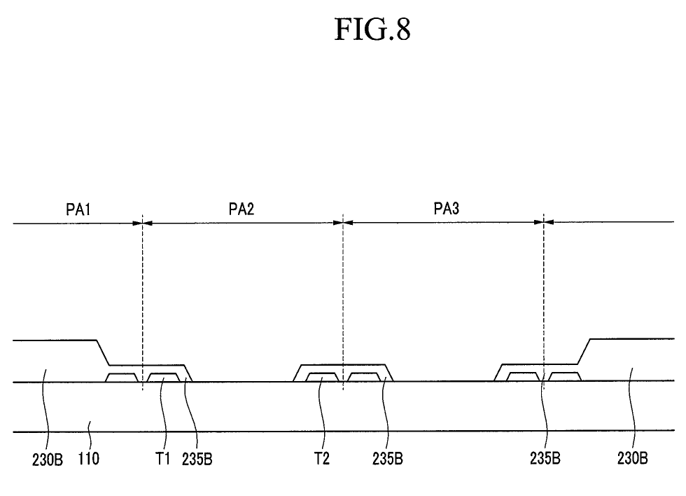

Next, as shown in FIG. 7, a blue photosensitive organic material 60 may be coated on the substrate 110 and the thin film transistors T1 and T2, and exposed by using a slit mask 80. Next, the exposed photosensitive organic material 60 may be developed to form a plurality of protecting members 235B on the thin film transistors T1 and T2 disposed in the pixels PA1, PA2, and PA3 and to simultaneously form a blue color filter 230B in the first pixel PA1, as shown in FIG. 8. By using the slit mask 80, the surface of the protecting member 235B may be lower than the surface of the blue color filter 230B.

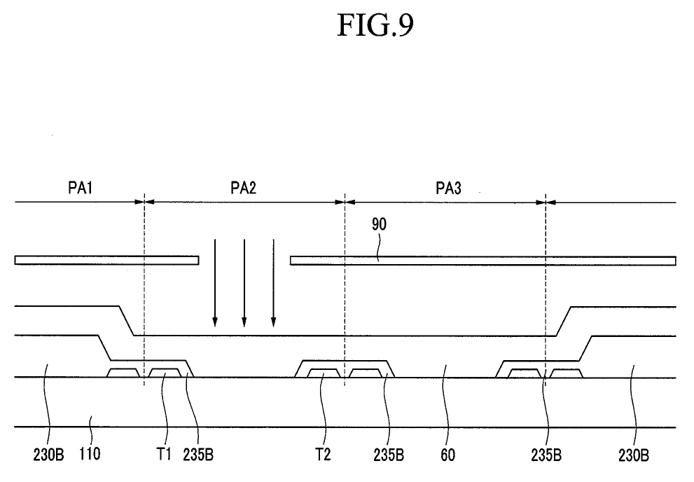

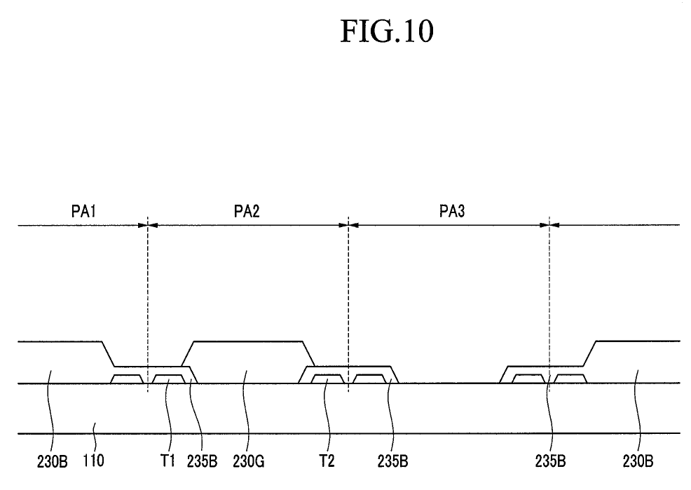

Next, as shown in FIG. 9, a green photosensitive organic material 60 may be coated on the substrate 110, the protecting members 235B, and the blue color filter 230B, and may be exposed by using a mask 90. Then, the exposed photosensitive organic material 60 may be developed to form a green color filter 230G in the second pixel PA2, as shown in FIG. 10. The edge of the green color filter 230G may overlap the protecting member 235B disposed in the second pixel PA2. In other embodiments, they may be not overlapped.

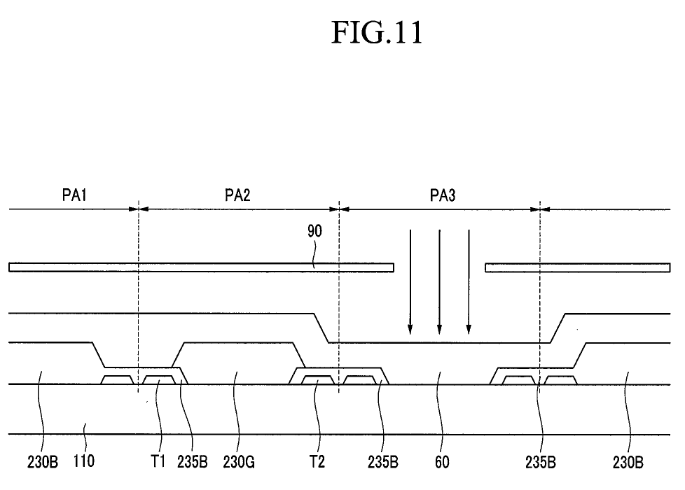

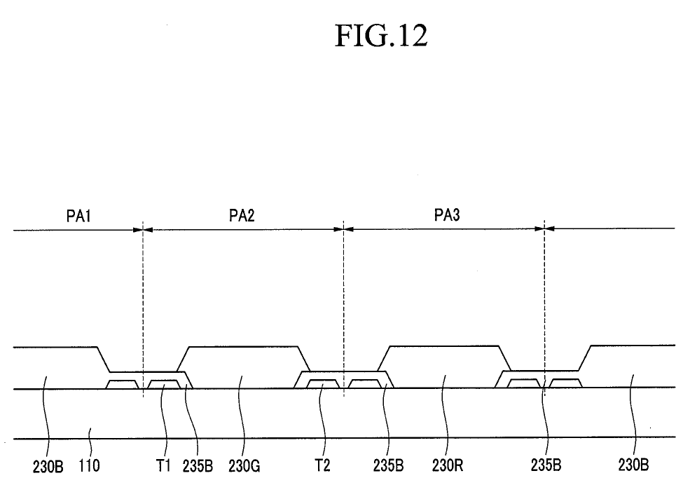

Next, as shown in FIG. 11, a red photosensitive organic material 60 may be coated on the substrate 110, the protecting member 235B, the blue color filter 230B, and the green color filter 230G, and may be exposed by using the mask 90. The exposed photosensitive organic material 60 may then be developed to form a red color filter 230R in the third pixel PA3, as shown in FIG. 12. The edge of the red color filter 230R may overlap the protecting member 235B in the third pixel PA3. In other embodiments, they may be not overlapped.

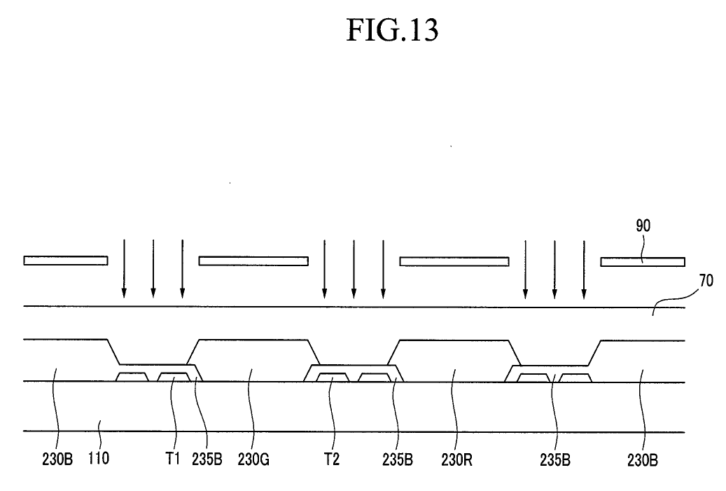

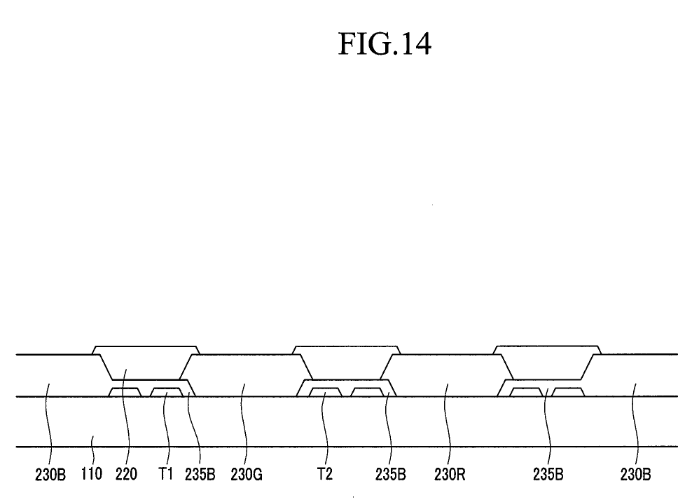

Next, as shown in FIG. 13, a light blocking material 70 may be deposited on the protecting member 235B and the color filters 230B, 230G, and 230R, and may be exposed by using the mask 90. The exposed light blocking material 70 may then be developed to form a light blocking member 220 on the protecting member 235B, as shown in FIG. 14. The height of the light blocking member 220 may be higher than the height of the other portions, and may be disposed in the concave portions enclosed by the color filters 230B, 230G, and 230R such that it may be easily coated and be stably formed. If the thickness of the light blocking member 220 is less than about 3 μm, the productivity characteristic is simplified. The light blocking member 220 may be designed to have the appropriate thickness by controlling the height of the protecting member 235B disposed thereunder.

Finally, as shown in FIG. 15, a capping layer 240 may be formed on the light blocking member 220 and the color filters 230B, 230G, and 230R, and a pixel electrode 191 including the first and second subpixel electrodes 191a and 191b may be formed on the capping layer 240. The first subpixel electrode 191a may be connected to the first thin film transistor T1 and the second subpixel electrode 191b may be connected to the second thin film transistor T2.

According to one or more exemplary embodiments of the present invention, the color filter may protect the channel portions, the source electrode and the drain electrode such that it is not necessary to additionally form a passivation layer. Accordingly, the manufacturing method becomes quicker and simplified, thereby improving productivity.

While this invention has been described in connection with what is presently considered to be practical exemplary embodiments, it is to be understood that embodiments of the invention are not limited to the disclosed embodiments, but, on the contrary, is intended to cover various modifications and equivalent arrangements included within the spirit and scope of the appended claims. The present exemplary embodiments are exemplarily described using a liquid crystal display, but the present invention may be adapted to various kinds of display devices including spacers.

What is claimed is:

1. A thin film transistor array panel comprising:
a substrate;
a plurality of first thin film transistors formed on the substrate;
a plurality of pixel electrodes connected to the first thin film transistors;
a plurality of color filters formed under or on the pixel electrodes and displaying various colors; and
a plurality of protecting members formed on the first thin film transistors,
wherein the protecting members have substantially the same color.

2. The thin film transistor array panel of claim 1, wherein the color of the color filters is a first color, a second color and a third color, and the color filters of the first color, the second color, and the third color are alternately arranged according to one direction.

3. The thin film transistor array panel of claim 2, wherein the protecting member contacts the first thin film transistor.

4. The thin film transistor array panel of claim 3, wherein the protecting member is a same layer as the color filter of the first color.

5. The thin film transistor array panel of claim 4, wherein one of the protecting members is connected to the color filter of the first color.

6. The thin film transistor array panel of claim 4, wherein the protecting member is disposed under edges of the color filter of the second color and the color filter of the third color.

7. The thin film transistor array panel of claim 4, wherein a surface of the protecting members is lower than a surface of the color filters.

8. The thin film transistor array panel of claim 1, further comprising a light blocking member formed on the protecting member.

9. The thin film transistor array panel of claim 8, further comprising a capping layer formed on the color filter and the light blocking member.

10. The thin film transistor array panel of claim 1, further comprising a storage electrode line formed on the substrate.

11. The thin film transistor array panel of claim 10, wherein the pixel electrodes respectively include:
a first subpixel electrode connected to the first thin film transistor, and
a second subpixel electrode separated from the first subpixel electrode.

12. The thin film transistor array panel of claim 11, further comprising a plurality of second thin film transistors connected to the second subpixel electrodes.

13. The thin film transistor array panel of claim 12, wherein an area of the first subpixel electrode is smaller than an area of the second subpixel electrode.

14. A liquid crystal display comprising:
a plurality of thin film transistors;
a plurality of pixel electrodes connected to the thin film transistors;
a common electrode facing the pixel electrodes;
a liquid crystal layer formed between the pixel electrode and the common electrode;
a plurality of color filters formed on or under the pixel electrode and displaying different colors; and
a plurality of protecting members formed on the thin film transistors,
wherein the protecting members have substantially the same color.

15. A method for manufacturing a thin film transistor array panel comprising:
forming a plurality of thin film transistors on a substrate;
forming first color filters in first pixels in each group of first to third pixels;
forming protecting members having a same color as the first color filters on the thin film transistors disposed on the first to third pixels of the groups;
forming second color filters in the second pixels of the groups;
forming third color filters in the third pixels of the groups; and
forming a plurality of pixel electrodes on the first to third color filters.

16. The method of claim 15, wherein the first, second, and third color filters have different colors.

17. The method of claim 16, wherein the first color filter and the protecting member are substantially simultaneously formed.

18. The method of claim 17, wherein the forming of the first color filter and the forming of the protecting member include:
coating an organic material having one of blue, green, and red colors in the first to third pixels, respectively, of the groups;
exposing the organic material by using a slit mask; and
developing the exposed organic material.

19. The method of claim 15, further comprising forming a light blocking member on the protecting member.

20. The method of claim 19, further comprising forming a capping layer on the first to third color filters and the light blocking member.
